(19) United States
(12) Patent Application Publication
(10) Pub. No.: US 2023/0401425 A1
(43) Pub. Date: Dec. 14, 2023

(54) APPARATUS FOR PREDICTING BATTERY LIFESPAN AND METHOD PREDICTING BATTERY LIFESPAN

(71) Applicants: Hyundai Motor Company, Seoul (KR); Kia Corporation, Seoul (KR); Industry-Academic Cooperation Foundation, Yonsei University, Seoul (KR)

(72) Inventors: Jaekyung Oh, Yongin-Si (KR); Chulkyu Lee, Anyang-Si (KR); Ju Seok Kim, Suwon-Si (KR); Hee Yeon Ryu, Yongin-Si (KR); Bohyun Lee, Incheon (KR); Kyeongeun Cho, Seoul (KR); Hangsoon Jung, Seoul (KR); Seongyoon Kim, Incheon (KR); Jung-Il Choi, Goyang-Si (KR)

(21) Appl. No.: 18/077,615

(22) Filed: Dec. 8, 2022

(30) Foreign Application Priority Data
Jun. 8, 2022 (KR) 10-2022-0069538

(51) Int. Cl. G06N 3/0442; H01M 10/42; G06N 3/08

(52) U.S. Cl. CPC G06N 3/0442; H01M 10/425; G06N 3/08; H01M 2010/4278

(57) ABSTRACT

A vehicle may include a display; a battery; a battery sensor configured to acquire battery data of the battery; and a processor configured to acquire an output of a battery lifespan model associated with the battery data, predict a lifespan value of the battery based on the output of the battery lifespan model, and display an indication associated with the lifespan value of the battery on the display. The battery lifespan model may include a cell lifespan model associated with a basic lifespan model trained using first battery cell data collected in a first operating environment. The cell lifespan model may use second battery cell data collected in a second operating environment, and a pack lifespan model may be trained using battery pack data collected in the first operating environment.

### CROSS-REFERENCE TO RELATED APPLICATION(S)

This application claims the benefit of priority to Korean Patent Application No. 10-2022-0069538, filed on Jun. 8, 2022 in the Korean Intellectual Property Office, the disclosure of which is incorporated herein by reference.

### TECHNICAL FIELD

The disclosure relates to an apparatus for predicting a battery lifespan, and a control method thereof.

### BACKGROUND

Vehicles include a moving device or a transportation device which may travel on a road or a track by using fossil fuel, electricity, or the like as a power source.

Research on electric vehicles using only electricity as an energy source is being actively conducted. A battery of an electric vehicle may serve as a driving energy source for moving the vehicle, and may also serve as an auxiliary energy source for providing convenience and safety to the driver.

The battery lifespan of electric vehicles decreases as a battery is used over time, and a battery capacity decreases according to the reduced lifespan. The battery of electric vehicles may be replaced if the battery capacity becomes 70 to 80% or less of the initial battery capacity of new batteries for reasons such as vehicle safety, charging time, mileage, and the like. A battery replacement cycle for electric vehicles may be approximately 5 to 10 years. In order to extend the battery replacement cycle, it is important to predict battery lifespan and manage the charging and discharging of the battery according to the predicted lifespan.

The battery capacity may decrease at various rates due to various causes such as non-uniform use environment, initial failure, malfunction, voltage deviation of battery cells, and the like. As such, the decrease in battery capacity may be uncertain due to various causes, and it may be difficult to predict the decrease in battery capacity due to the uncertainty.

### SUMMARY

The following summary presents a simplified summary of certain features. The summary is not an extensive overview and is not intended to identify key or critical elements.

An aspect of the disclosure is to provide a vehicle for predicting a remaining battery lifespan, an apparatus for predicting a battery lifespan, and a control method thereof, which use machine learning.

An aspect of the disclosure is to provide a vehicle, an apparatus for predicting a battery lifespan, and a control method thereof, which can convert a battery lifespan model trained in a specific environment into a battery lifespan model trained in another environment using transfer learning.

An aspect of the disclosure is to provide a vehicle, an apparatus for predicting a battery lifespan, and a control method thereof, which can generate a battery lifespan model of a battery module or battery pack using a battery lifespan model trained based on a battery cell.

A vehicle may comprise: a display; a battery; a battery sensor configured to acquire battery data of the battery; and a processor configured to: acquire an output of a battery lifespan model associated with the battery data; predict a lifespan value of the battery based on the output of the battery lifespan model; and display an indication associated with the lifespan value of the battery on the display, wherein the battery lifespan model comprises: a cell lifespan model associated with a basic lifespan model trained using first battery cell data collected in a first operating environment, wherein the cell lifespan model is trained using second battery cell data collected in a second operating environment; and a pack lifespan model trained using battery pack data collected in the first operating environment and an output of the cell lifespan model.

An apparatus may comprise: a storage configured to store first battery data; an input interface configured to acquire second battery data from a vehicle; a processor configured to: train, using the first battery data, a battery lifespan model for predicting a lifespan of a battery of the vehicle; acquire, based on the second battery data, an output of the trained battery lifespan model; and predict, based on the output of the trained battery lifespan model, a lifespan value of the battery; and an output interface configured to transmit the predicted lifespan value of the battery to the vehicle, wherein the battery lifespan model comprises: a basic lifespan model associated with first battery cell data collected in a first operating environment; a cell lifespan model associated with second battery cell data collected in a second operating environment; and a pack lifespan model associated with an output of the cell lifespan model and battery pack data collected in the first operating environment.

A method may comprise: storing, by an apparatus, first battery data; acquiring second battery data from a vehicle; training, using the first battery data, a battery lifespan model to predict a lifespan of a battery of the vehicle; acquiring, based on the second battery data, an output of the trained battery lifespan model; determining, based on the output of the trained battery lifespan model, a predicted lifespan value of the battery; and transmitting, to the vehicle, the predicted lifespan value of the battery, wherein the training the battery lifespan model comprises: training, using first battery cell data collected in a first operating environment, a basic lifespan model; associating, using second battery cell data collected in a second operating environment, the basic lifespan model with a cell lifespan model; and training, using an output of the cell lifespan model and battery pack data collected in the first operating environment, a pack lifespan model.

These and other features and advantages are described in greater detail below.

### BRIEF DESCRIPTION OF THE DRAWINGS

These and/or other aspects of the disclosure will become apparent and more readily appreciated from the following description of various examples, taken in conjunction with the accompanying drawings of which:

FIG. 1 is a view illustrating a configuration of an apparatus for predicting a battery lifespan;

FIGS. 2 and 3 illustrate examples of a battery lifespan model included in an apparatus for predicting a battery lifespan;

FIG. 4 is a view illustrating a configuration for training a battery lifespan model included in an apparatus for predicting a battery lifespan;

FIG. 5 illustrates a lifespan prediction result according to the related art;

FIG. 6 illustrates a lifespan prediction result of the battery lifespan model by a transfer learning process illustrated in FIG. 4;

FIG. 7 illustrates an example of a configuration for training a battery lifespan model included in an apparatus for predicting a battery lifespan;

FIG. 8 illustrates an example of a configuration for training a battery lifespan model included in an apparatus for predicting a battery lifespan;

FIG. 9 illustrates an example of a vehicle including a lifespan model; and

FIG. 10 illustrates an example of a server and a vehicle, which include an apparatus for predicting a battery lifespan.

### DETAILED DESCRIPTION

Like reference numerals refer to like elements throughout the specification. This specification does not describe all elements of the disclosed embodiment(s) and detailed descriptions of what is well known in the art or redundant descriptions on substantially the same configurations have been omitted. The terms ‘part’, ‘module’, ‘member’, ‘block’ and the like as used in the specification may be implemented in software and/or hardware. Further, a plurality of ‘part’, ‘module’, ‘member’, ‘block’ and the like may be embodied as one component. It is also possible that one ‘part’, ‘module’, ‘member’, ‘block’ and the like includes a plurality of components.

Throughout the specification, when an element is referred to as being “connected to” another element, it may be directly or indirectly connected to the other element and the “indirectly connected to” includes being connected to the other element via a wireless communication network.

Also, when a part “includes” a certain component, it means that other components may be further included, rather than excluding other components, unless otherwise stated.

Throughout the specification, when a member is located “on” another member, this includes not only when one member is in contact with another member but also when another member is present between the two members.

The terms first, second, and the like are used to distinguish one component from another component, and the component is not limited by the terms described above.

An expression used in the singular encompasses the expression of the plural, unless it has a clearly different meaning in the context.

The reference numerals used in operations are used for descriptive convenience and are not intended to describe the order of operations and the operations may be performed in a different order unless otherwise stated.

Hereinafter, the working principle and examples of the disclosure will be described with reference to the accompanying drawings.

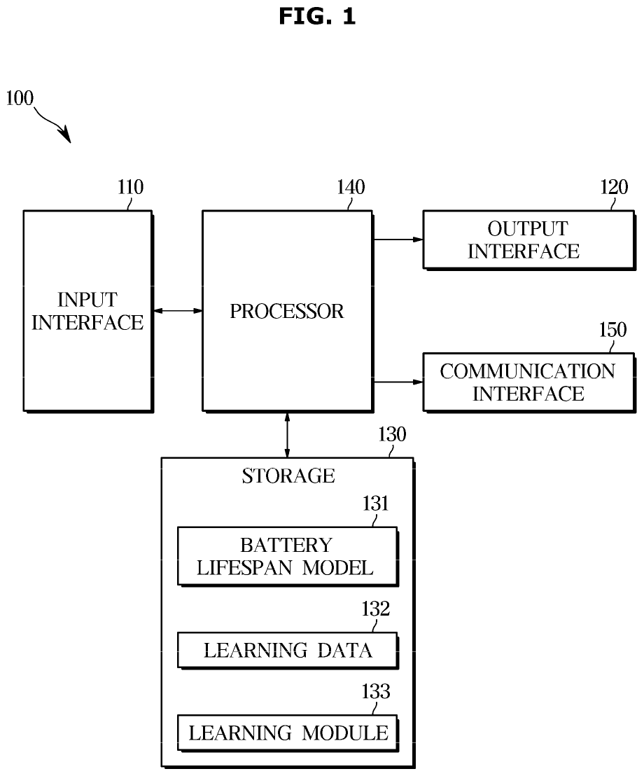

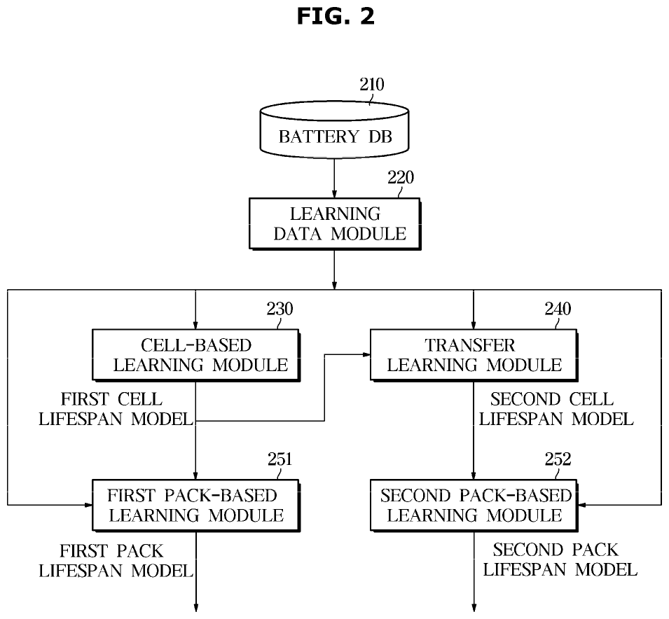

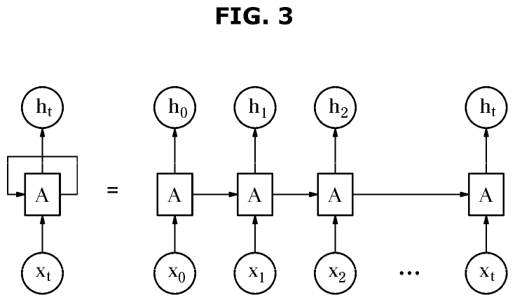

FIG. 1 is a view of a configuration of an apparatus for predicting a battery lifespan. FIGS. 2 and 3 illustrate examples of a battery lifespan model included in an apparatus for predicting a battery lifespan.

An apparatus 100 for predicting a battery lifespan may determine battery data (e.g., to predict the remaining battery lifespan), for example, after a predetermined charge/discharge cycle by using current battery data. For example, the apparatus 100 for predicting lifespan may predict a maximum charge voltage of a battery after a predetermined charge/discharge cycle, for example, based on the discharge voltage, discharge current, discharge cycle, occurrence/non-occurrence of deep discharge, charge voltage, charge current, charge cycle, and number of times of charging of the battery during a charge/discharge cycle, a maximum charge voltage after the charge/discharge cycle, or the like.

As illustrated in FIGS. 1, 2, and 3, the apparatus 100 for predicting a battery lifespan may include an input interface 110, an output interface 120, a storage 130, a processor 140, and a communication interface 150.

The input interface 110 may receive and acquire a user input of a user who manages/controls the apparatus 100 for predicting a battery lifespan and/or learning data for training an artificial intelligence algorithm.

For example, the input interface 110 may include a user interface that receives a control instruction from a user (e.g., a designer of a vehicle controller, a simulator tester of a vehicle controller, etc.). The input interface 110 may include a character input device (e.g., a keyboard), a point input device (e.g., a mouse, a trackball, etc.), and the like.

The input interface 110 may include a connection interface for receiving learning data. For example, the input interface 110 may include a universal serial bus (USB) interface, a display output interface (e.g., an HDMI interface, a DVI interface, an RGB interface), and the like.

The input interface 110 may include a communication interface for receiving learning data from an external device. For example, the input interface 110 may acquire learning data from an external device using a wireless communication method (e.g., Wi-Fi®, Bluetooth®, Zigbee®, etc.).

The output interface 120 may output information related to the battery lifespan predicted by the apparatus 100.

As described above, the apparatus 100 may output the maximum charge voltage of the battery, for example, after a predetermined charge/discharge cycle through the output interface 120.

The output interface 120 may include a display that (e.g., directly) displays information related to the battery lifespan to the user, a connection interface for outputting information related to the battery lifespan to an external device, and/or a communication interface for transmitting information related to the battery lifespan to an external device.

The storage 130 may store a program and/or data for predicting a remaining battery lifespan.

For example, the storage 130 may store a battery lifespan model 131 for predicting a remaining battery lifespan, learning data 132 for training the battery lifespan model 131, and a learning model 133 for training the battery lifespan model 131 using the learning data 132.

The battery lifespan model 131 may predict a remaining battery lifespan from battery data. For example, the trained battery lifespan model 131 may predict a remaining battery lifespan based on the battery data including the discharge voltage, discharge current, discharge cycle, occurrence/non-occurrence of deep discharge, charge voltage, charge current, charge cycle, and number of times of charging of the battery during a charge/discharge cycle, a maximum output voltage after the charge/discharge cycle, and the like. For example, the battery lifespan model 131 may be trained to predict the maximum output voltage of the battery after a predetermined charge/discharge cycle, based on the battery data.

The battery lifespan model 131 may be trained by a supervised learning that performs learning under the guidance of a manager, an unsupervised learning that performs learning without a manager's guidance, a reinforcement learning that performs learning by reward without a manager's guidance, or the like. Hereinafter, one or more examples will be described in a condition that the battery lifespan model 131 is trained by the supervised learning. However, an unsupervised learning, a reinforcement learning, and/or other machine learning schemes may be used (e.g., additionally or alternatively).

The battery lifespan model 131 may include various learning model algorithms. For example, the battery lifespan model 131 may include a neural network model, a support vector machine (SVM) algorithm, an AdaBoost algorithm, a random forest algorithm, and the like. Hereinafter, one or more examples will be described in a condition that the battery lifespan model 131 includes a neural network model. However other learning model algorithm(s) may be included in the battery lifespan model 131 (e.g., additionally or alternatively).

The battery lifespan model 131 may include a recurrent neural network (RNN) model. A recurrent neural network is a sequence model that processes inputs and outputs in sequence units. The recurrent neural network is designed to process data sequences.

As illustrated in FIG. 3, the recurrent neural network may include an input layer X_t, a hidden layer A, and an output layer h_t. Also, another output of the hidden layer A may be input to the hidden layer A again (e.g., as a feedback in a feedback loop).

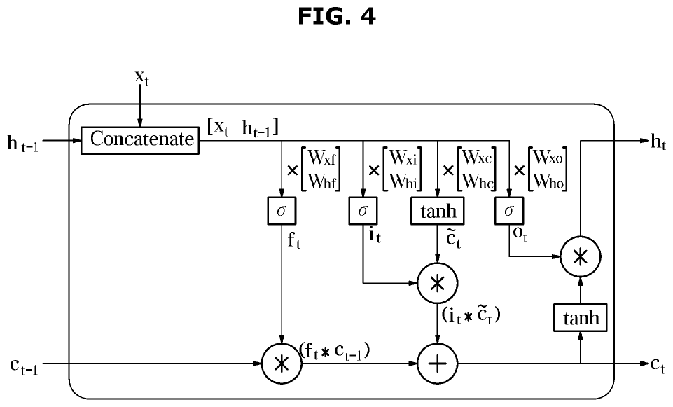

As such, the output of the hidden layer A of the recurrent neural network recursively cycles. The current output of the hidden layer may depend on the previous output of the hidden layer. As illustrated in FIGS. 3 and 4, in the recurrent neural network, hidden layers may be concatenated.

In an example, the battery lifespan model 131 may include a long short term memory model (LSTM), which is a type of a recurrent neural network.

The LSTM can overcome a vanishing gradient problem known as the problem of the recurrent neural network. The vanishing gradient problem is associated with a case in which an interval (a sequence interval) between an relevant input and an output that uses the input is large and learning ability decreases.

As shown in FIG. 4, the hidden layer of the LSTM may acquire a hidden state output h_t−1 of the previous hidden layer, a cell state output C_t−1 of the previous hidden layer, and an input x_t of the current hidden layer, and output a hidden state output h_t of the current hidden layer, and a cell state output C_t of the current hidden layer. In the current hidden layer of the LSTM, the hidden state output h_t−1 and the input x_t may be redirected into vectors [x_t, h_t−1].

The current hidden layer of the LSTM may be defined by the following equations.

In the current hidden layer of the LSTM, f_t, i_t, Ĉ_t, and σ_t may be calculated, for example, based on at least two of: the input x_t of the current hidden layer, the hidden state output h_t−1 of the previous hidden layer, and the hidden output C_t−1 of the previous hidden layer (e.g., using x_t and h_t−1 as illustrated in FIG. 4). The output h_t and the output C_t of the current layer may be acquired, for example, based on the calculated f_t, i_t, C̊_t, σ−_t, and C_t−1.

fₜ=σ(xₜW_{xf}+hₜ₋₁W_{hf}+b_{f}) Equation 1

Here, σ(⋅) represents a sigmoid function, x_t represents an input inputted to the current hidden layer, h_t−1 represents a hidden state output of the previous hidden layer, W_xf and W_hf represent weights, and b_f represents a bias (which could be zero if there is no bias). W_xf, W_hf, and b_f are initially set to arbitrary values (or vectors), and may be determined and updated by a learning process.

iₜ=σ(xₜW_{zi}+hₜ₋₁Wₕᵢ+bᵢ) Equation 2

Here, σ(⋅) represents a sigmoid function, x_t represents an input inputted to the current hidden layer, h_t−1 represents a hidden state output of the previous hidden layer, W_xi and W_hi represent weights, and b_i represents a bias (which could be zero if there is no bias). W_xi, W_hi, and b_i are initially set to arbitrary values (or vectors), and may be determined and updated by a learning process.

\tilde{C}ₜ=tanh(xₜWₓₑ+hₜ₋₁W_{hc}+b_{c})Equation 3

Here, tanh(⋅) represents a hyperbolic tangent function, x_t represents an input inputted to the current hidden layer, h_t−1 represents a hidden state output of the previous hidden layer, W_xc and W_hc represent weights, b_c represents a bias (which could be zero if there is no bias). W_xc, W_hc, and b_c are initially set to arbitrary values (or vectors), and may be determined and updated by a learning process.

Cₜ=fₜ*Cₜ₋₁iₜ*\tilde{C}ₜ Equation 4

Here, f_t represents an output value (or output vector) calculated by Equation 1, C_t−1 represents a cell state output of the previous hidden layer, i_t represents an output value (or an output vector) calculated by Equation 2, Ĉ_t represents an output value (or output vector) calculated by Equation 3. Here, the operator “*” may be a multiplication operation or a Hadamard product, and the operator “+” may be an addition operation.

oₜ=o(xₜWₓₒ+hₜ₋₁Wₕₒ+bₒ) Equation 5

Here, σ(⋅) represents a sigmoid function, x_t represents an input inputted to the current hidden layer, h_t−1 represents a hidden state output of the previous hidden layer, W_xo and W_ho represent weights, and b_o represents a bias (which could be zero if there is no bias). W_xo, W_ho, and b_o are initially set to arbitrary values (or vectors), and may be determined and updated by a learning process.

hₜ=oₜ*tanh(Cₜ) Equation 6

Here, h_t represents a hidden state output of the current hidden layer, o_t represents an output value (or an output vector) calculated by Equation 5, tanh(⋅) represents a hyperbolic tangent function, and C_t represents a cell state output of the current hidden layer.

As such, the LSTM may output an output value (or an output vector) depending on an input of the current hidden layer (x_t), a hidden state output of the previous hidden layer (h_t−1), and a cell state output of the previous hidden layer (c_t−1).

In the LSTM, a plurality of hidden layers may be concatenated.

The battery lifespan model 131 may further include a fully connected (FC) layer for outputting a learned output (e.g., an output vector) based on an output of the LSTM.

The FC layer may be defined by the following equation.

yₜ=hₜW_{hy}+b_{y} Equation 7

Here, y_t represents an output of the battery lifespan model 131, h_t represents an output of the LSTM, W_hy represents a weight, and b_y represents a bias (which could be zero if there is no bias). W_hy and b_y are initially set to arbitrary values (or vectors), and may be determined and updated by a learning process.

As such, the battery lifespan model 131 may include an LSTM part (a cyclic neural network) and an FC part (a fully connected layer).

However, the battery lifespan model 131 is not limited to the recurrent neural network, and may include other types of artificial intelligence algorithms such as a convolutional neural network (CNN).

Referring back to FIG. 1, the battery lifespan model 131 may be trained in advance based on the learning data 132.

The learning data 132 may include battery data and vector data including a measured remaining battery lifespan corresponding to the battery data. For example, the learning data 132 may include measured battery data including the discharge voltage, discharge current, discharge cycle, occurrence/non-occurrence of deep discharge, charge voltage, charge current, charge cycle, and number of times of charging of the battery during a charge/discharge cycle, a maximum output voltage after the charge/discharge cycle, etc., and a battery lifespan corresponding to the measured battery data (e.g., a maximum output voltage after a predetermined charge/discharge cycle). The measured battery data and the remaining battery lifespan may be stored in a form of vector data.

The battery lifespan model 131 may be trained based on learning data collected in a specific environment. For example, the battery lifespan model 131 may be trained by the learning data collected from a specific type of vehicle, trained by the learning data collected from a vehicle in which a specific driving motor is installed, and/or trained by the learning data collected at a specific temperature.

The learning module 133 may train the battery lifespan model 131 using the learning data 132.

For example, the learning module 133 may input the input data of the learning data into the battery lifespan model 131 and acquire an output of the battery lifespan model 131, for example, based on or in response to the input data of the input learning data. The learning module 133 may adjust the weight W and/or bias b of the battery lifespan model 131, for example, based on a difference (e.g., an error) between the output of the battery lifespan model 131 and the output data of the learning data. Specifically, the learning module 133 may calculate the weight W and bias b of the battery lifespan model 131 so that an error between the output of the battery lifespan model 131 and the output data of the learning data is minimized.

By an iterative learning process, the weight W and bias b of the battery lifespan model 131 may be gradually modified to converge to a value (or a vector) for indicating a relation between the input data and output data of the learning data.

The processor 140 may output information related to the battery lifespan, for example, by the program and/or data stored in the storage 130 executed by the processor 140.

For example, the processor 140 may process the training of the battery lifespan model 131 (e.g., by executing the learning module 133 stored in the storage 130). The processor 140 may input the learning data 132 to the battery lifespan model 131 (e.g., by executing the learning module 133 stored in the storage 130), and may train the battery lifespan model 131 based on the output of the battery lifespan model 131.

The processor 140 may include one or more processing cores and memory. The processing core(s) load the battery lifespan model 131, the learning data 132, and learning module 133 stored in the storage 130 on the memory, and according to a series of instructions included in the learning module 133, the battery lifespan model 131 may be trained with the learning data 132.

Also, the processor 140 may output the trained battery lifespan model 131.

The battery lifespan model 131 and the learning module 133 implemented as software have been described. The battery lifespan model 131 and the learning module 133 implemented as software may be stored in the storage 130, loaded on the memory by the processor 140, and processed by the processor 140. The processor 140 may be any general-purpose processor(s) configured to perform one or more learning processes/algorithms described herein (e.g., by executing instructions stored in the storage 130 or any other storage storing the instructions implementing the one or more learning processes/algorithms).

However, the battery lifespan model 131 and the learning module 133 are not limited to software. For example, the battery lifespan model 131 and the learning module 133 may be implemented in special-purpose hardware device(s) executing one or more instructions (e.g., one or more processors configured to perform one or more learning processes/algorithms described herein).

As hardware, the battery lifespan model 131 and the learning module 133 may be implemented in the processor 140 as hardware. The processor 140 may be a special-purpose processor. The battery lifespan model 131 may include a hidden layer as a hardware component, and a connection between the hidden layers may be updated by a learning process.

As such, in order to improve the accuracy of lifespan prediction and efficiently training of the battery lifespan model 131, the processor 140 may train the battery lifespan model 131 by using the learning data collected in a specific environment.

The battery lifespan model 131 trained in a specific environment may be redirected to another environment. For example, the battery lifespan model 131 may be trained using the learning data collected from an older vehicle. As such, the battery lifespan model 131 trained by the data of the older vehicle may be used to predict the battery lifespan of a new vehicle.

In order to predict the battery lifespan of the new vehicle, the battery lifespan model 131 trained based on the data of the older vehicle may be transferred through learning.

The processor 140 may retrain the battery lifespan model 131 trained by the data of the older vehicle using the data of the new vehicle.

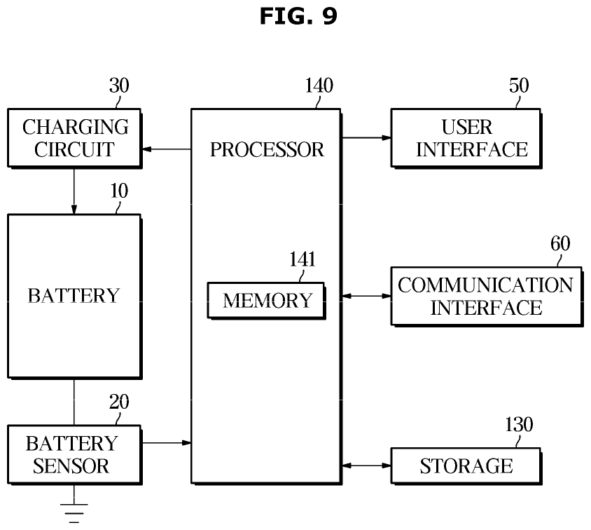

The communication interface 150 may be the same or similar to a communication interface 60 shown in FIG. 9 and described below.

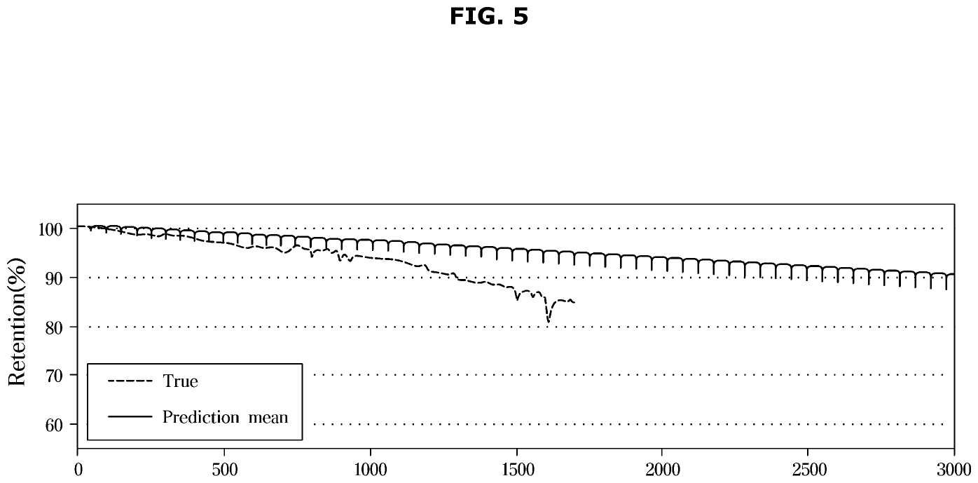

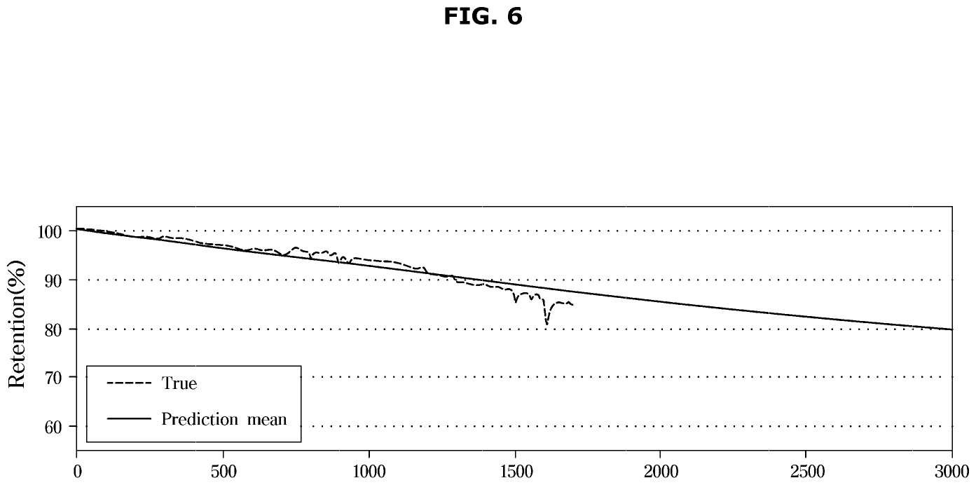

FIG. 2 is a view illustrating a configuration for training a battery lifespan model included in an apparatus for predicting battery lifespan. FIG. 5 illustrates a lifespan prediction result according to the related art. FIG. 6 illustrates a lifespan prediction result of the battery lifespan model by transfer learning illustrated in FIG. 2. Transfer of learning (or transfer of learning) may refer to the use of previously acquired knowledge and skills in new learning or problem-solving situations.

As illustrated in FIG. 2, an apparatus (e.g., the apparatus 100 for predicting a battery lifespan or any other apparatus) may include a battery database 210, a learning data module 220, a cell-based learning module 230, a transfer learning module 240, and a first pack-based learning module 251, and/or a second pack-based learning module 252. The learning data module 220, the cell-based learning module 230, the transfer learning module 240, the first pack-based learning module 251, and/or the second pack-based learning module 252 may be implemented as software and/or hardware.

The battery database 210 may include battery data used in various environments. For example, the battery database 210 may include the discharge voltage, discharge current, discharge cycle, occurrence/non-occurrence of deep discharge, charge voltage, charge current, charge cycle, and number of times of charging of the battery during a charge/discharge cycle, a maximum output voltage after the charge/discharge cycle, or the like.

The learning data module 220 may provide learning data suitable for each of the cell-based learning module 230, the first pack-based learning module 251, the transfer learning module 240, and/or the second pack-based learning module 252.

For example, the learning data module 220 may provide the cell-based learning module 230 with the cell data collected in a first operating environment, and the transfer learning module 240 with the cell data collected in a second operating environment. The learning data module 220 may provide the first pack-based learning module 251 with the pack data collected in the first operating environment, and provide the second pack-based learning module 252 with the pack data collected in the second operating environment.

The cell-based learning module 230 may train the battery lifespan model 131 based on the cell data operating in a specific environment (e.g., the first operating environment). For example, the cell-based learning module 230 may train the battery lifespan model 131 by using battery data of each battery cell that supplies power to a specific type of driving motor in a specific type of vehicle.

The cell-based learning module 230 may train the first cell lifespan model. The first cell lifespan model may be a battery lifespan model trained using the learning data collected in the first operating environment.

The transfer learning module 240 may retrain the first cell lifespan model that has trained by the cell-based learning module 230 using the learning data in a specific environment by using learning data in another environment. In other words, the transfer learning module 240 may train the first cell lifespan model using the learning data collected in different environment(s).

For example, the learning data for training the battery lifespan model may be collected while the vehicle is actually moving. While a plurality of users drives (shares) the vehicle, the vehicle may collect learning data and transmit the collected learning data to the apparatus 100 for predicting a battery lifespan.

Accordingly, the apparatus 100 may collect data about the battery included in the type of vehicle currently on sale (especially the type of vehicle that has been sold for a certain period of time). The battery lifespan model 131 trained using the battery data of a battery included in the type of vehicle currently on sale (especially a type of vehicle that has been sold for a long time) may more accurately predict the battery lifespan.

On the other hand, there may be insufficient data on batteries included in vehicles that are still under development. For batteries included in vehicles under development, data may be collected during testing. However, the amount of data may be insufficient to accurately train the battery lifespan model 131.

The transfer learning module 240 may further train the first cell lifespan model in order to divert the already trained first cell lifespan model to another vehicle (e.g., a vehicle under development). The transfer learning module 240 may output the additionally trained second cell lifespan model.

As described above, the battery lifespan model may include the LSTM part and the FC part. The battery lifespan model 131 may be defined by the following equation.

Y=f_{FC}(f_{LSTM}(X_{A})) Equation 8

Here, Y represents an output of a trained battery lifespan model, X_A represents input data collected in a first operating environment, f_LSTM(⋅) represents the LSTM part of a trained battery lifespan model, and f_FC(⋅) represents the FC part of a trained battery lifespan model.

The LSTM part may reflect a capacity reduction pattern of a typical battery cell, and the FC part may reflect a capacity reduction pattern of a battery cell in a specific operating environment. In other words, among the battery data, data indicating the capacity reduction pattern of a typical battery cell may affect the learning of the LSTM part, and data indicating the capacity reduction pattern of a battery cell in a specific operating environment may affect the learning of the FC part learning.

The LSTM part of the battery lifespan model trained by data of a specific environment be used to predict the battery lifespan in various environments (e.g., other than the specific environment).

The transfer learning module 240 may use the characteristics of the battery lifespan model including the LSTM part and the FC part, redirect the LSTM part of the battery lifespan model, and may newly train the FC part of the battery lifespan using data collected in different environments.

The transfer learning module 240 may train the FC part f_FC(⋅) of the trained battery lifespan model without training the LSTM part f_LSTM(⋅) of the trained battery lifespan model. Specifically, the weight W and bias b included in the LSTM part f_LSTM(⋅) of the trained battery lifespan model may be maintained by the data collected in the first operating environment (e.g., the type of vehicle already on sale). The weight W and bias b included in the FC part f_FC(⋅) of the battery lifespan model may be newly trained based on the data collected in the second operating environment (for example, the type of vehicle currently being developed).

By newly training the FC part f_FC(⋅) of the battery lifespan model based on the data collected in the second operating environment, the lifespan prediction performance of the battery lifespan model in the second operating environment may be improved.

For example, in a case of predicting the battery lifespan in the second operating environment using the first cell lifespan model without transfer learning, a difference between the battery lifespan predicted by the first cell lifespan model (a maximum output voltage after a predetermined cycle) and a measured battery lifespan is large as illustrated in FIG. 5. On the other hand, in a case of predicting the battery lifespan in the second operating environment using the second cell lifespan model transferred through learning, a difference between the battery lifespan predicted by the second cell lifespan model (a maximum output voltage after a predetermined cycle) and a measured battery lifespan is significantly reduced as illustrated in FIG. 6.

Referring back to FIG. 2, the first pack-based learning module 251 may train the battery pack-based first pack lifespan model using the output data of the first cell lifespan model corresponding to the cell data and the pack data collected in the first operating environment.

The battery of a vehicle may operate as a battery pack including a plurality of battery cells. A plurality of battery cells connected in series with each other may form a battery pack, and the battery pack may provide power to a driving motor of a vehicle or the like. In general, a high voltage power is required to generate a high torque for a driving motor of a vehicle. On the other hand, each of the battery cells may typically output a low voltage. For example, lithium-ion battery cells widely used as batteries for electric vehicles output power having a nominal voltage of about 3.7 V. A battery with 100 Li-ion battery cells connected in series can output power with a nominal voltage of approximately 370 V.

In this case, it may be difficult to define a battery pack lifespan as a simple sum of the lifespans of the battery cells. For example, the battery pack lifespan may not have a linear relationship with the lifespans of the battery cells due to a voltage variation between battery cells, an aging variation between battery cells, and the like.

The first pack-based learning module 251 may convert the first cell lifespan model into a first pack lifespan model by using the pack data collected in the first operating environment.

For example, the prediction of the lifespans of a plurality of battery cells may be defined by the following equation.

γ^{(s)}=f_{FC}(f_{LSTM}(X^{(s)})),s=1,2, . . . ,S Equation 9

Here, Y(S) represents an output of a trained battery lifespan model for a battery cell index s, X(s) represents input data collected in a first operating environment, and f_LSTM(⋅) represents the LSTM part of a trained battery lifespan model, f_FC(⋅) represents the FC part of a trained battery lifespan model.

The battery pack lifespan may be defined by the following equation.

$$Y = {\sum }_{s} {W}^{( s )} {Y}^{( s )} , {\sum }_{s} {W}^{( s )} = 1 \qquad Equation 9$$

Here, Y represents data representing a battery pack lifespan (e.g., a maximum output voltage of the battery pack after a predetermined charge/discharge cycle), W(s) represents a weight of a battery cell having the battery cell index s, and Y(s) represents the data representing the lifespan of the battery cell having the battery cell index s (e.g., a maximum output voltage of the battery cell having the battery cell index s after a predetermined charge/discharge cycle). W(s) may be trained from a deviation between the outputs of a first cell lifespan model input to the first pack-based learning module 251.

The first pack lifespan model may be defined by the following equation.

[W⁽¹⁾,W⁽²⁾, . . . ,W^{(S)}]^{T}=g([X⁽¹⁾,X⁽²⁾, . . . ,X^{(S)}]^{T}) Equation 10

Here, W(s) may represent a weight of a battery cell having the battery cell index s, X(s) represents a plurality of data collected from the battery cell having the battery cell index s, and g(⋅) represents a first pack lifespan model.

For example, g(⋅) may include Gaussian process (GP), which is a basic machine learning method. However, the disclosure is not limited thereto, and g (⋅) may include various machine learning algorithms such as a neural network algorithm.

The first pack-based learning module 251 may train the first pack lifespan model using the cell data and pack data collected in the first operating environment. The first pack-based learning module 251 may input the cell data collected in the first operating environment to the first cell lifespan model, and acquire data regarding the lifespan of each of the battery cells from the first cell lifespan model. The first pack-based learning module 251 may train the first pack lifespan model by using data on the lifespan of each of the battery cells and the pack data collected in the first operating environment.

The first pack-based learning module 251 may input data regarding the lifespan of each of the battery cells to the first pack lifespan model, and the weight W(s) may be calculated so that an error between the output data of the first pack lifespan model and the pack data collected in the first operating environment is minimized. By an iterative learning process, the weight W(s) may be gradually adjusted to a value (or vector) for indicating the relation between the input data and output data of the learning data.

The apparatus 100 may predict a battery pack lifespan operating in the first operating environment (e.g., a maximum output voltage after a predetermined charge/discharge cycle) by using the first cell lifespan model and the first pack lifespan model.

The second pack-based learning module 252 may train the second pack lifespan model by using the pack data and output data of the second cell lifespan model corresponding to the cell data. For example, the second pack-based learning module 252 may input the cell data collected in the second operating environment to the second cell lifespan model, and acquire data on the lifespan of each of the battery cells from the second cell lifespan model. The second pack-based learning module 252 may train the second pack lifespan model by using data on the lifespan of each of the battery cells and the pack data collected in the second operating environment.

The second pack-based learning module 252 may input data about the lifespan of each of the battery cells into the second pack lifespan model, and the weight W(s) may be calculated so that an error between the output data of the second pack lifespan model and the pack data collected in the second operating environment is minimized. By an iterative learning process, the weight W(s) may be gradually adjusted to a value (or a vector) for indicating the relation between the input data and output data of the learning data.

The apparatus 100 may predict a battery pack lifespan (e.g., a maximum output voltage after a predetermined charge/discharge cycle) operating in the second operating environment (e.g., a new vehicle that has not yet been sold) by using the second cell lifespan model and the second pack lifespan model, which are transferred through learning by the transfer learning module 230.

As described above, the apparatus 100 may retrain a learning model that has been trained using battery data of a specific environment by using battery data of another environment. As a result, the apparatus 100 may predict the lifespan of a battery installed in a new vehicle having insufficient learning data, and may save data and time for learning a new lifespan prediction model.

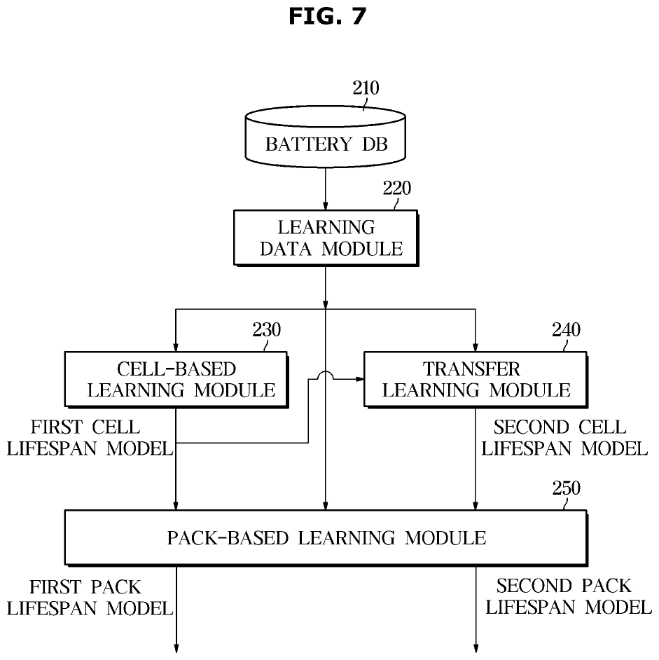

FIG. 7 illustrates an example of a configuration for training a battery lifespan model included in an apparatus for predicting a battery lifespan.

With reference to FIG. 7, the apparatus (e.g., the apparatus 100 or any other apparatus) may include the battery database 210, the learning data module 220, the cell-based learning module 230, the transfer learning module 240, and/or the pack-based learning module 250. The learning data module 220, the cell-based learning module 230, the transfer learning module 240, and/or the pack-based learning module 250 may be implemented as software and/or hardware. The battery database 210, the learning data module 220, the cell-based learning module 230, and the transfer learning module 240 may be the same as the battery database, the learning data module, the cell-based learning module, and the transfer learning module illustrated in FIG. 4, respectively.

The pack-based learning module 250 may train the pack lifespan model using the pack data collected in the first operating environment.

For example, the cell-based learning module 230 may train the first cell lifespan model by using a plurality of cell data collected in the first operating environment. The transfer learning module 240 may perform the transfer leaning from the first cell lifespan model to the second cell lifespan model by using a small number of cell data collected in the second operating environment. The pack-based learning module 250 may train the pack lifespan model using the output data of the first cell lifespan model corresponding to the cell data of the first operating environment and the small number of pack data collected in the first operating environment.

The non-linearity between the lifespans of battery cells and the battery pack lifespan is not due to the operating environment, but rather may be due to variations between the battery cells (e.g., charge voltage or degree of aging, etc.). Accordingly, the pack lifespan model trained using the battery data collected in the first operating environment may be used to predict the battery pack lifespan operating in the second operating environment.

The pack lifespan model trained using battery data (e.g., cell data and pack data) collected in the first operating environment may be used to predict the lifespan of the battery pack operating in the first operating environment as well as the lifespan of the battery pack operating in the second operating environment.

The apparatus may predict the lifespan of the battery pack operating in the first operating environment by using the first cell lifespan model and the pack lifespan model, and predict the lifespan of the battery pack operating in the second operating environment by using the second cell lifespan model and the pack lifespan model.

As described above, the apparatus may use the pack lifespan model trained in a specific operating environment to predict the lifespan of the battery operating in various operating environment. Accordingly, it may be possible to save data and time to train the pack lifespan model separately.

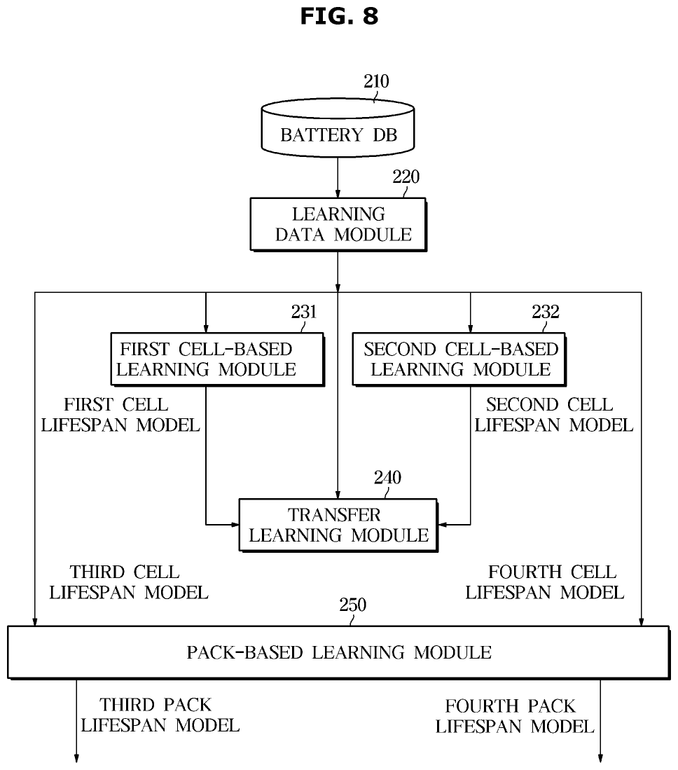

FIG. 8 illustrates an example of a configuration for training a battery lifespan model included in an apparatus for predicting a battery lifespan.

As illustrated in FIG. 8, the apparatus (e.g., the apparatus 100) may include the battery database 210, the learning data module 220, a first cell-based learning module 231, a second cell-based learning module 232, the transfer learning module 240, and/or the pack-based learning module 250. The learning data module 220, the first cell-based learning module 231, the second cell-based learning module 232, the transfer learning module 240, and/or the pack-based learning module 250 may be implemented as software and/or hardware. The battery database 210 and the learning data module 220 may be the same as the battery database and the learning data module illustrated in FIG. 4, respectively.

The first cell-based learning module 231 may train the first cell lifespan model by using the first cell data collected in the first operating environment. Also, the second cell-based learning module 232 may train the second cell lifespan model by using the second cell data collected in the second operating environment. The training process of the second cell-based learning module 232 may be the same as (or similar to) the training process of the first cell-based learning module 231.

The transfer learning module 240 may convert the first cell lifespan model and/or the second cell lifespan model into a third lifespan model by using the third cell data collected in the third operating environment. In other words, the transfer learning module 240 may output (create) the third cell lifespan model by retraining the first cell lifespan model using the third cell data, and/or retraining the second cell lifespan model using the third cell data, so the third cell lifespan model can be output (created).

The pack-based learning module 250 may train the pack lifespan model using the first pack data collected in the first operating environment and/or the second pack data collected in the second operating environment.

For example, the first cell-based learning module 231 may train the first cell lifespan model using a plurality of cell data collected in the first operating environment. The second cell-based learning module 232 may train the second cell lifespan model using a plurality of cell data collected in the second operating environment. The transfer learning module 240 may perform the transfer learning from the first cell lifespan model or the second cell lifespan model to the third cell lifespan model by using a small number of cell data collected in the third operating environment. The pack-based learning module 250 may train the pack lifespan model by using the small number of first pack data collected in the first operating environment and/or the small number of second pack data collected in the second operating environment.

The pack lifespan model trained using the first pack data and/or the second pack data may be used to predict the lifespan of the battery pack operating in the third operating environment.

The apparatus may predict the lifespan of the battery pack operating in the third operating environment by using the pack lifespan model trained using the first pack data and/or the second pack data.

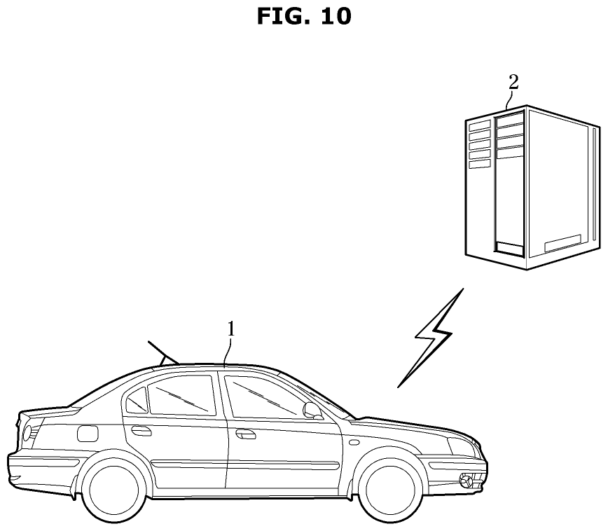

FIG. 9 illustrates an example of a vehicle including a lifespan model. FIG. 10 illustrates an example of a server and a vehicle.

As illustrated in FIG. 9, the vehicle 1 may include a battery 10, a battery sensor a charging circuit 30, a user interface 50, a communication interface 60, a storage 130, and a processor 140. The vehicle 1 may include the battery lifespan model trained by the apparatus 100.

The battery 10 may store electrical energy and may supply power to a load (e.g., a motor and/or other components) of the vehicle 1.

The battery sensor 20 may detect an output (output voltage, output current, etc.) of the battery 10. Also, the battery sensor 20 may output battery data indicating a state of charge of the battery 10. For example, the battery sensor 20 may determine a state of charge (SoC) of the battery 10 based on the output voltage, output current, and temperature of the battery 10. The state of charge of the battery 10 may indicate a degree to which electrical energy is stored in the battery 10. The state of charge generally has a value of 0 to 100%, and may indicate a degree to which the battery 10 is charged between a deep discharge state (0%) and a full charge rate (100%). The state of charge of the battery 20 may be calculated based on an open circuit voltage (OCV) of the battery 10 and an input/output current of the battery 20.

The battery sensor 20 may be electrically connected to the processor 140, and may provide the battery data of the battery 10 to the processor 140.

The charging circuit 30 may allow or block charging of the battery 10 from an external power source according to a control instruction of the processor 140. The charging circuit 30 may control a charge voltage and/or a charge current for charging the battery 10 according to a control instruction of the processor 140.

The user interface 50 may acquire a user input of the user and display projection information in response to the user input. For example, the user interface may include a touch screen. The touch screen may sense a user's touch input and display image information in response to the sensed touch input.

The communication interface 60 may communicate with an external device. For example, the communication interface 60 may wirelessly transmit and receive communication signals to and from an external device. The communication interface may wirelessly communicate with a base station or access point (AP), and may access a wired communication network through a base station or access point. The communication interface 60 may also communicate with external devices connected to a wired communication network via a base station or an access point. For example, the communication interface 60 wirelessly communicates with an access point (AP) using Wi-Fi (WiFi™, IEEE 802.11 technology standard), and/or communicates with a base station using CDMA, WCDMA, GSM, long term evolution (LTE), WiBro, etc. The communication interface 50 may also receive data from external devices via a base station or access point.

The storage 130 may store a program and/or data for controlling operations of the vehicle 1.

The storage 130 may store the lifespan model trained by the apparatus 100. The lifespan model may include a cell lifespan model and a pack lifespan model. The lifespan model may predict the lifespan of the battery 10 (e.g., a maximum output voltage after a predetermined charge/discharge cycle, etc.) based on the cell data collected from battery cells included in the battery 10.

The processor 140 may predict the lifespan of the battery 10 using the lifespan model stored in the storage 130 and control operations of the vehicle 1 depending on the predicted lifespan.

The processor 140 may include a memory 141 that temporarily stores a lifespan model and battery data. The processor 140 and the memory 141 may be implemented as separate semiconductor devices or as a single semiconductor device.

The memory 141 may include a volatile memory such as a static random access memory (S-RAM) and a dynamic random access memory (D-RAM), or a non-volatile memory such as a read only memory (ROM) and an erasable programmable read only memory (EPROM). The memory 141 may include a single memory device or a plurality of memory devices.

The processor 140 may include a microprocessor, a microcontroller, an application specific integrated circuit (ASIC), or a field programmable gate array (FPGA). The processor 140 may include a single processor or a plurality of processors.

The processor 140 may receive battery data including cell data from the battery sensor 20. The processor 140 may input battery data into the lifespan model stored in the memory 141 and acquire output data of the lifespan model. The processor 140 may predict the lifespan of the battery 10 (e.g., a maximum output voltage after a predetermined charge/discharge cycle, etc.) based on the output data of the lifespan model.

If the lifespan of the battery 10 is less than a reference value, the processor 140 may display an indication (e.g., a video message indicating aging of the battery or output a voice message) associated with the remaining lifespan of the battery through the user interface 50.

The processor 140 may control the charging circuit 30 to limit the charge voltage and/or charge current for charging the battery 10 if the lifespan of the battery 10 is less than a reference value.

Referring to FIGS. 9 and 10, the processor 140 may control the communication interface 60 to transmit battery data to the server 2 as illustrated in FIG. 10 in order to more accurately predict the lifespan of the battery 10. Each of the vehicle 1 and the server 2 may include the apparatus 100 or part of the apparatus 100.

The server 2 may include a lifespan model for more accurately predicting a lifespan. For example, the lifespan model of the server 2 may include more hidden layers than the hidden layers of the lifespan model of the vehicle 1. Thereby, the lifespan model of the server 2 can predict the lifespan of the battery 10 more accurately than the lifespan model of the vehicle 1.

The server 2 may predict the lifespan of the battery 10 of the vehicle 1 based on the battery data received from the vehicle 1, and may transmit data corresponding to the predicted lifespan to the vehicle 1. The vehicle 1 may receive data from the server 2 and identify the lifespan of the vehicle 1.

The server 2 may further train the lifespan model based on the battery data of the battery 10 received from the vehicle 1 and/or one or more other vehicles. In this way, by further training the lifespan model, the server 2 may improve the lifespan prediction accuracy of the lifespan model.

As described above, the vehicle 1 may predict the lifespan of the battery 10 using the lifespan model, and display a message to the user or control the charging circuit 30 according to the predicted lifespan.

A vehicle according to an aspect of the disclosure may include a display; a battery; a battery sensor configured to acquire battery data of the battery; and a processor configured to acquire an output of a battery lifespan model corresponding to the battery data, predict a lifespan value of the battery based on the output of the battery lifespan model, display a message recommending replacement of the battery on the display based on the lifespan value of the battery less than or equal to a predetermined value. The battery lifespan model may include a cell lifespan model associated with a basic lifespan model trained using first battery cell data collected in a first operating environment, wherein the cell lifespan model is trained using second battery cell data collected in a second operating environment; and a pack lifespan model trained using battery pack data collected in the first operating environment.

The lifespan value of the battery may include a maximum output voltage of the battery predicted after a predetermined charge and discharge cycle.

The cell lifespan model may include a long short term memory model (LSTM) and a fully connected (FC) layer.

The LSTM and the FC layer may be trained using the first battery cell data collected in the first operating environment.

The trained FC layer may be trained using the second battery cell data collected in the second operating environment.

The vehicle may further include a charging circuit configured to charge the battery. The processor may be further configured to control a charge current for charging the battery so that the charge current is limited based on the lifetime value of the battery less than or equal to the predetermined value.

The vehicle may further include a communication interface configured to communicate with an external device. The processor may be further configured to transmit the battery data to the external device and receive an output of the battery lifespan model from the external device.

An apparatus for predicting a battery lifespan according to an aspect of the disclosure may include a storage configured to store first battery data; an input interface configured to acquire second battery data from a vehicle; a processor configured to train a battery lifespan model for predicting a lifespan of a battery using the first battery data, acquire an output of the trained battery lifespan model corresponding to the second battery data, predict a lifespan value of the battery based on an output of the battery lifespan model; and an output interface configured to transmit the lifespan value of the battery predicted by the processor to the vehicle. The processor may include a cell-based learning module configured to train a basic lifespan model using first battery cell data collected in a first operating environment; a transfer learning model configured to transfer through learning the basic lifespan model to a cell lifespan model using second battery cell data collected in a second operating environment; and a pack-based learning model configured to train a pack lifespan model using an output of the transfer learning model and battery pack data collected in the first operating environment.

A method for predicting a battery lifespan according to an aspect of the disclosure may include storing first battery data; acquiring second battery data from a vehicle; training a battery lifespan model to predict a lifespan of a battery using the first battery data; acquiring an output of the trained battery lifespan model corresponding to the second battery data; predicting a lifespan value of the battery based on an output of the battery lifespan model; and transmitting a predicted lifespan value of the battery to the vehicle. The training the battery lifespan model may include training a basic lifespan model using first battery cell data collected in a first operating environment, transferring through learning the basic lifespan model to a cell lifespan model using second battery cell data collected in a second operating environment, and training a pack lifespan model using an output of the transfer learning model and battery pack data collected in the first operating environment.

According to an aspect of the present disclosure, it may be possible to provide a vehicle for predicting a remaining battery lifespan, an apparatus for predicting a battery lifespan, and a control method thereof, which use machine learning. Accordingly, the apparatus for predicting a battery lifespan can accurately predict a remaining lifespan of a battery of an electric vehicle.

According to an aspect of the present disclosure, it may be possible to provide a vehicle, an apparatus for predicting a battery lifespan, and a control method thereof, which can convert a battery lifespan model trained in a specific environment into a battery lifespan model trained in another environment using transfer learning. Accordingly, even if the data for learning is insufficient, the apparatus for predicting a battery lifespan may train a battery lifespan model of a battery, and the amount of computation for training the battery lifespan model may be reduced.

According to an aspect of the present disclosure, it may be possible to provide a vehicle, an apparatus for predicting a battery lifespan, and a control method thereof, which can generate a battery lifespan model of a battery module or battery pack using a battery lifespan model trained based on a battery cell. Accordingly, even if there is not enough data for training the battery life model of the battery module or battery pack, the apparatus for predicting a battery lifespan may generate the battery life model of the battery module or battery pack using the battery lifespan model of the battery cell.

Various examples have been described with reference to the accompanying drawings as described above. Those of ordinary skill in the art to which the present disclosure pertains will understand that the disclosure may be implemented in other forms than the disclosed embodiment(s) without changing the technical spirit or essential features of the disclosure. The disclosed embodiment(s) are illustrative and should not be construed as limiting.

What is claimed is:

1. A vehicle comprising:
a display;
a battery;
a battery sensor configured to acquire battery data of the battery; and
a processor configured to:
acquire an output of a battery lifespan model associated with the battery data;
predict a lifespan value of the battery based on the output of the battery lifespan model; and
display an indication associated with the lifespan value of the battery on the display,
wherein the battery lifespan model comprises:
a cell lifespan model associated with a basic lifespan model trained using first battery cell data collected in a first operating environment, wherein the cell lifespan model is trained using second battery cell data collected in a second operating environment; and
a pack lifespan model trained using battery pack data collected in the first operating environment and an output of the cell lifespan model.

2. The vehicle of claim 1, further comprising:
a communication interface to receive the first battery cell data,
wherein each of the first battery cell data and the battery pack data is associated with at least one battery of at least one second vehicle, and
wherein the second battery cell data is associated with the battery data of the battery.

3. The vehicle of claim 1, wherein the lifespan value of the battery comprises a maximum output voltage of the battery predicted after a charge and discharge cycle.

4. The vehicle of claim 1, wherein the cell lifespan model comprises a long short-term memory (LSTM) model and a fully connected (FC) layer.

5. The vehicle of claim 4, wherein the LSTM model and the FC layer are trained using the first battery cell data collected in the first operating environment.

6. The vehicle of claim 5, wherein the trained FC layer is further trained using the second battery cell data collected in the second operating environment.

7. The vehicle of claim 1, wherein the vehicle further comprises a charging circuit configured to charge the battery, and
wherein the processor is further configured to control a charge current for charging the battery so that the charge current is limited based on the lifespan value of the battery being less than or equal to a threshold value.

8. The vehicle of claim 1, wherein the vehicle further comprises a communication interface configured to communicate with an external device, and
wherein the processor is further configured to transmit the battery data to the external device and receive an output of the battery lifespan model from the external device.

9. An apparatus comprising:
a storage configured to store first battery data;
an input interface configured to acquire second battery data from a vehicle;
a processor configured to:
train, using the first battery data, a battery lifespan model for predicting a lifespan of a battery of the vehicle;
acquire, based on the second battery data, an output of the trained battery lifespan model; and
predict, based on the output of the trained battery lifespan model, a lifespan value of the battery; and
an output interface configured to transmit the predicted lifespan value of the battery to the vehicle,
wherein the battery lifespan model comprises:
a basic lifespan model associated with first battery cell data collected in a first operating environment;
a cell lifespan model associated with second battery cell data collected in a second operating environment; and
a pack lifespan model associated with an output of the cell lifespan model and battery pack data collected in the first operating environment.

10. The apparatus of claim 9, further comprising:
a communication interface to receive, from at least one second vehicle, the first battery data,
wherein each of the first battery cell data and the battery pack data is associated with at least one battery of the at least one second vehicle, and
wherein the second battery cell data is associated with the battery of the vehicle.

11. The apparatus of claim 9, wherein the lifespan value of the battery comprises a maximum output voltage of the battery predicted after a charge and discharge cycle.

12. The apparatus of claim 9, wherein the cell lifespan model comprises a long short-term memory (LSTM) model and a fully connected (FC) layer.

13. The apparatus of claim 12, wherein the processor is further configured to train the LSTM model and the FC layer using the first battery cell data collected in the first operating environment.

14. The apparatus of claim 13, wherein the processor is further configured to train the trained FC layer using the second battery cell data collected in the second operating environment.

15. A method comprising:
storing, by an apparatus, first battery data;
acquiring second battery data from a vehicle;
training, using the first battery data, a battery lifespan model to predict a lifespan of a battery of the vehicle;
acquiring, based on the second battery data, an output of the trained battery lifespan model;
determining, based on the output of the trained battery lifespan model, a predicted lifespan value of the battery; and
transmitting, to the vehicle, the predicted lifespan value of the battery,
wherein the training the battery lifespan model comprises:
training, using first battery cell data collected in a first operating environment, a basic lifespan model;
perform transfer learning from the basic lifespan model to a cell lifespan model using second battery data collected in a second operating environment; and
training, using an output of the cell lifespan model and battery pack data collected in the first operating environment, a pack lifespan model.

16. The method of claim 15, further comprising:
receiving, from at least one second vehicle, the first battery data,
wherein each of the first battery cell data and the battery pack data is associated with at least one battery of the at least one second vehicle, and
wherein the second battery cell data is associated with the battery of the vehicle.

17. The method of claim 15, wherein the predicted lifespan value of the battery comprises a maximum output voltage of the battery predicted after a configured charge and discharge cycle.

18. The method of claim 15, wherein the cell lifespan model comprises a long short-term memory (LSTM) model and a fully connected (FC) layer.

19. The method of claim 18, further comprising:
training the LSTM and the FC layer using the first battery cell data collected in the first operating environment.

20. The method of claim 19, wherein the training the battery lifespan model further comprises performing transfer learning of the trained FC layer using the second battery cell data collected in the second operating environment.
